(19) United States
(12) Patent Application Publication
(10) Pub. No.: US 2026/0164618 A1
(43) Pub. Date: Jun. 11, 2026

(54) INTEGRATED SERVER CABINET ALLOWING FOR WASTE HEAT RECOVERY AND CONTROL METHOD

(71) Applicant: Hangzhou Dare Rouhan Technology Co., Ltd., Hangzhou (CN)

(72) Inventors: Risheng LI, Hangzhou (CN); Minghui SUN, Hangzhou (CN); Shuwei LIU, Hangzhou (CN); Sheng LI, Hangzhou (CN)

(73) Assignee: Hangzhou Dare Rouhan Technology Co., Ltd., Hangzhou (CN)

(21) Appl. No.: 19/180,091

(22) Filed: Apr. 15, 2025

(30) Foreign Application Priority Data
Aug. 28, 2024 (CN) 202411192703.9

(51) Int. Cl. H05K 7/20

(52) U.S. Cl. CPC H05K 7/20836; H05K 7/20781

(57) ABSTRACT

An integrated server cabinet allowing for waste heat recovery includes a plurality of servers, a cooling distribution unit, a waste heat utilization module, and a control component. The plurality of servers are placed on units in a plurality of rows and columns; the cooling distribution unit includes a primary circulation pipeline; a waste heat utilization module includes a secondary circulation pipeline; the primary circulation pipeline and the secondary circulation pipeline are configured to adjust water flow rates in the primary circulation pipeline and the secondary circulation pipeline on line through an electric three-way regulating valve, and the primary circulation pipeline is configured to: cool and dissipate heat for the plurality of servers; and the secondary circulation pipeline is used as a bypass branch of a liquid cooling system, and is configured to: recover waste heat, and undertake a part or all of heat exchange functions of the primary circulation pipeline.

### CROSS-REFERENCE TO RELATED APPLICATIONS

This application claims priority to Chinese Patent Application No. 202411192703.9 with a filing date of Aug. 28, 2024. The content of the aforementioned application, including any intervening amendments thereto, is incorporated herein by reference.

### TECHNICAL FIELD

The present disclosure belongs to the field of server technologies, relates to an integrated server cabinet, and in particular, relates to an integrated server cabinet allowing for waste heat recovery and a control method.

### BACKGROUND

In the era of big data explosion, especially with development of the artificial intelligence (AI) technology, an amount of data is growing exponentially, and more and more memory space is occupied by stored files. In order to ensure data security, timely storage, invoking convenience, and the like, most companies have their own enterprise servers for timely uploading, storage, backup, transfer, and the like of data files. Servers that are configured to carry all electronic data information of enterprises are crucial to the enterprises. In the current information age where big data is king, once the server fails, normal operation and management of the enterprise will be directly affected, and therefore, stable operation of server is crucial.

Due to the importance of servers, dedicated areas or rooms are set by many enterprises for the servers, and corresponding cooling measures are matched to ensure good and continuous operation of highly integrated servers. During a high-speed continuous operation and cooling process of the server, a large amount of heat is emitted directly into the atmosphere, and suitable cooling measures need to be matched for cooling. A lot of energy is consumed by a cooling device, and heat emitted is directly discharged and cannot be recovered in a timely manner, and consequently, a large amount of energy is consumed during the operation of the server. In addition to the costs of a server device, energy consumption during operation also becomes a part of enterprise costs.

### SUMMARY OF THE PRESENT INVENTION

To resolve problems, the present disclosure provides an integrated server cabinet allowing for waste heat recovery and a control method. To resolve problems in the conventional technology, a primary circulation pipeline and a secondary circulation pipeline are disposed. The primary circulation pipeline is configured to cool a server and the secondary circulation pipeline is configured to: achieve heat exchange, recover heat dissipated by the server, and connect to an external component with a heat source need to meet supply of a hot water source. In addition, water flow can be adjusted on line according to a temperature of an external environment, heat supply needs at different temperatures are met under different conditions, and through recovery, better environment-friendly needs are achieved while energy costs of enterprises are reduced.

To resolve the foregoing technical problems, the present disclosure adopts the following technical solution. An integrated server cabinet allowing for waste heat recovery and a control method are provided. The integrated server cabinet allowing for waste heat recovery includes a plurality of servers, a cooling distribution unit, a waste heat utilization module, a control component, and a plate heat exchange component.

The cooling distribution unit includes a primary circulation pipeline, the primary circulation pipeline serves as a cooling source and is configured to cool and dissipate heat for the plurality of servers through medium circulation.

The waste heat utilization module includes a secondary circulation pipeline for waste heat recovery so as to provide heat supply to an external component with a heat source need. The primary circulation pipeline and the secondary circulation pipeline are configured to adjust flow rates, in the primary circulation pipeline and the secondary circulation pipeline, of a heated-up medium on line through an electric three-way regulating valve, to allow a whole system to switch among including a primary temperature control mode, a waste heat utilization mode, and a secondary temperature control mode.

A medium that is heated up by the plurality of servers and that is in the primary circulation pipeline is used as heat source supply of the plate heat exchange component, and after being heat-exchanged by the plate heat exchange component, a part of the medium that is cooled flows back into the primary circulation pipeline, and a rest part of the medium that is heated up is used as a supply source of a heat source in the secondary circulation pipeline. In the present application, the plate heat exchange component is adopted. For example, the technical solution of the present application also can be implemented by another structure capable of achieving medium heat exchange on the market in consideration of factors of costs and mounting space within a protection range of the present application.

Further, the integrated server cabinet further includes a cabinet body. A plurality of server stands are disposed in the cabinet body, the plurality of servers are placed on the server stands in a plurality of rows and columns, the cabinet body is divided into upper and lower portions, the upper portion is configured to place the plurality of servers, the lower portion is configured to place the cooling distribution unit and the plate heat exchange component, and is placed with a pipeline, a skid-mounted structure is formed by the cooling distribution unit, the primary circulation pipeline is disposed on a back surface of the cabinet in a reversed return layout, and a flexible connection for preventing the cooling distribution unit from vibrating is disposed between the primary circulation pipeline and the cooling distribution unit.

Further, the primary circulation pipeline includes a primary circulation pump, a primary-circulation master water inlet pipeline, and a primary-circulation master water return pipeline, one server corresponds to one water inlet branch and one water outlet branch, the primary-circulation master water inlet pipeline is simultaneously accessed into cooling areas of the plurality of servers through a plurality of water inlet branches, and then is returned to the primary-circulation master water return pipeline through water outlet branches, and a valve for controlling on and off of water flow is separately disposed on each water inlet branch and each water outlet branch.

From a fan of a dry cooler to the server, the primary-circulation master water inlet pipeline is sequentially provided with a first valve, a primary water circulation flow meter FIT01, and a primary inlet water temperature signal meter TT01; from the server to the fan of the dry cooler, the primary-circulation master water return pipeline is sequentially provided with a primary return water temperature signal meter TT02, a primary circulation water pump P01, an electric three-way regulating valve V001, and a second valve V002; the primary water circulation flow meter FIT01 is configured to feed back a signal to the control component; and the control component is configured to: compare a fed-back value of the primary water circulation flow meter FIT01 with a set target flow rate through a proportion integration differentiation (PID) algorithm module and adjust a frequency of the primary circulation water pump, making a value of the primary water circulation flow meter FIT01 be close to the set target flow rate.

Further, the secondary circulation pipeline includes a secondary circulation pump, a secondary-circulation water inlet main pipe, and a secondary return water temperature signal meter TT11, and further includes an outdoor temperature signal meter TT21, and an indoor temperature signal meter TT22, where the secondary return water temperature signal meter TT11 is configured to feed back a signal to the control component; and both the outdoor temperature signal meter TT21 and the indoor temperature signal meter TT22 are electrically connected to the control component to feed back a real-time temperature to the control component.

Further, a water outlet end of the plate heat exchange component is divided into two branches, one branch is configured to return a cooled medium into the primary-circulation master water inlet pipeline in the primary circulation pipeline, and is connected between a first valve V003 and a primary water circulation flow meter FIT01, and the other branch is connected to the external component with a heat source need.

Further, in a structural layout, a length and a width of the cooling distribution unit are not greater than a length and a width of the cabinet, to reserve space for the server; if an electric three-way regulating valve is mounted at a water inlet of the plate heat exchange component, a tee joint is diverged; or if an electric three-way regulating valve is mounted at a water outlet of the plate heat exchange component, the tee joint is converged.

Further, specifications of a product are determined through parameter calculation according to the following steps:
S1, determining a total power of the plurality of servers, and rounding after calculating an amplification coefficient according to the total power to determine a heat exchange power of the cooling distribution unit;
S2, calculating a flow rate of a primary circulation pump, where a primary circulation temperature difference Δt is obtained according to a difference between an ultimate inlet water temperature and an ultimate outlet water temperature of the server, and the flow rate of the primary circulation pump is calculated according to the following formulas:

$$Q = cm Δ t ;$$

$$Q = c ( ρ V ) Δ t ;$$

$$V = Q / ( c ρΔ t ) ;$$

wherein, characteristic of a cooling medium include a freezing point, a boiling point, a density, and a specific heat capacity; C represents the specific heat capacity, and represents a capability of heat required to increase a temperature of an object, the unit of the specific heat capacity is Joule per Kilogram-Celsius; m represents a mass of the object, Δt represents an amount of temperature change, namely, an increased (or a decreased) temperature of the object; p: represents a density of the object, and represents a ratio of a material mass to a volume, measured in kilogram per cubic meter; and V: represents a volume of the object, measured in cubic meter; and the flow rate is determined by finally setting the amplification coefficient;
S3, calculating a lift of the primary circulation pump, selecting a pipeline specification, and determining a specific frictional resistance of a pipeline according to the selected pipeline specification,
   where a calculation formula for a pipeline resistance loss is ΔP=L·Δp; L is equal to a sum of a length of the pipeline, a length of an elbow, a length of a tee joint, a length of a valve group, a length of the plate heat exchange component, and a length of the server, namely, L is an equivalent length of a most unfavorable loop for primary circulation; Δp represents the specific frictional resistance of the pipeline, and the lift of the primary circulation pump is greater than Δp;
S4: calculating a flow path and a lift of a secondary circulation pump, where a calculation process is same as a calculation process of the primary circulation pump, and a difference lies in that L is equal to a sum of the length of the pipeline, the length of the elbow, the length of the valve group, the length of the plate heat exchange component, and a length of a heating end, namely, L is an equivalent length of a most unfavorable loop for secondary circulation;
S5, performing plate heat exchange component model selection, where a power of the plate heat exchange component is equal to or slightly greater than a power sum of the plurality of servers; and then calculating a heat exchange area by performing the plate heat exchange component model selection according to a difference between a primary supply water temperature and a primary return water temperature, and a difference between a secondary supply water temperature and a secondary return water temperature; and
S6, determining model selection of the pipeline, a pipe fitting, and the valve group, where a pipeline with an optimal specific frictional head loss is selected by rounding up the flow rates in the primary circulation pipeline and the secondary circulation pipeline into an integer, and a square pipe is selected as a vertical pipe, thus utilizing space more effectively while specific frictional resistances in the primary circulation pipeline and in the secondary circulation pipeline being close to each other; and selecting a same pipe diameter for the pipe fitting and the valve group.

A control method for an integrated server cabinet allowing for waste heat recovery includes a primary return water temperature control mode, a waste heat utilization control mode, and a climate compensation automatic control mode that are switchable.

In the primary return water temperature control mode, a primary return water temperature control method is as follows:

1.1) setting a target primary return water temperature TT91; 1.2) performing opening degree and rotation speed adjustment on an electric three-way regulating valve V001 and a fan of a dry cooler G01/G02 through a Proportional Integral Derivative (PID) algorithm module; and 1.3) making a value showing on a primary inlet water temperature signal meter TT01 be close to the target primary return water temperature TT91.

In the waste heat utilization control mode, the control method is as follows:

2.1) setting the target primary return water temperature TT91 and the target secondary return water temperature TT92; 2.2) comparing the target secondary return water temperature TT92 with a value showing on a secondary return water temperature signal meter TT11, and determining whether waste heat utilization is needed; performing opening degree and rotation speed adjustment on the electric three-way regulating valve V001 and the fan of the dry cooler G01/G02 through the PID algorithm module; 2.3) making the value showing on the primary inlet water temperature signal meter TT01 be close to the target primary return water temperature TT91; and 2.4) returning to the step 2.1) after stabilizing for a period of time to readjust.

In the climate compensation automatic control mode, the control method is as follows:

3.1) calculating a target secondary return water temperature TT94 according to an outdoor temperature TT21; 3.2) performing frequency adjustment on a secondary circulation water pump P02 through the PID algorithm module; making TT11 be close to the target secondary return water temperature TT94; 3.4) performing tail temperature control; 3.5) setting a target indoor temperature TT96; 3.6) performing frequency adjustment on the secondary circulation water pump P02 through the PID algorithm module; 3.7) making a value showing on an indoor temperature signal meter TT22 be close to the target indoor temperature TT96; 3.8) performing heat supply circulation water temperature control; 3.9) setting a target heat supply return water temperature TT92; 3.10) performing frequency adjustment on the secondary circulation water pump P02 through the PID algorithm module; and 3.11) making the value showing on the secondary return water temperature signal meter TT11 be close to the target heat supply return water temperature TT92.

Further, the waste heat utilization mode control method is specifically as follows:
1), manually setting the target primary temperature TT91 with a first tolerance of +2° C., wherein the target primary temperature TT91 and the first tolerance need to be displayed on a settings screen; and manually setting the target secondary temperature TT92 with a second tolerance of +2° C., wherein the target secondary temperature value TT92 and the second tolerance need to be displayed on the settings screen;
2), comparing the value showing on the secondary return water temperature signal meter TT11 with the target secondary temperature TT92, performing step 3) when the value showing on the secondary return water temperature signal meter TT11 is no less than the target secondary temperature TT92; and performing step 5) when the value showing on the secondary return water temperature signal meter TT11 is less than the target secondary temperature TT92;
3), setting an access of a dry cooler of the electric three-way regulating valve (V001) to 100%, setting an access of a plate heat exchange component to 0%, comparing the target primary temperature TT91 with the value showing on the primary inlet water temperature signal meter TT01) performing frequency adjustment on the fan of the dry cooler G01/G02 through the PID algorithm module, and making the value showing on the primary inlet water temperature signal meter TT01 be infinitely close to the target primary temperature TT91;
4), setting a time interval (time02), starting to count for the time interval (time02) after heat supply balance is achieved, and automatically return to step 2) to readjust after counting is ended, wherein a readjustment time interval needs to be displayed on the settings screen;
5), setting the access of the dry cooler of the electric three-way regulating valve V001 to 0%, and setting the access of the plate heat exchange component to 100%;
6), comparing the value showing on the primary inlet water temperature signal meter TT01 with the target primary temperature TT91, performing step 7) when the value showing on primary inlet water temperature signal meter TT01 is greater than the target primary temperature TT91; performing step 8) when the value showing on primary inlet water temperature signal meter TT01 is less than the target primary temperature TT91; and performing step 9) when the value showing on primary inlet water temperature signal meter TT01 is equal to the target primary temperature TT91;
7), slowly increasing the access of the dry cooler and slowly decreasing the access of the plate heat exchange component, and when an opening degree of the access of the plate heat exchange component is less than or equal to 20%, adjusting a rotation speed of the fan of the dry cooler G01/G02 to slowly increase through the PID algorithm module until an effect that the value showing on primary inlet water temperature signal meter TT01 is equal to the target primary temperature TT91 is achieved in step 9);
8), adjusting the rotation speed of the fan of the dry cooler G01/G02 to slowly decrease through the PID algorithm module, and after the fan of the dry cooler is stopped, slowly decreasing the access of the dry cooler and slowly increasing the access of the plate heat exchange component until the effect that the value showing on primary inlet water temperature signal meter TT01 is equal to the target primary temperature TT91 is achieved in step 9);
9), keeping a current opening degree of the electric three-way regulating valve V001 and keeping a current rotation speed of the fan of the dry cooler G01/02;
10), setting the time interval (time02), starting to count for the time interval (time02) after heat supply balance is achieved, and automatically return to step 2) to readjust after counting is ended, wherein a readjustment time interval needs to be displayed on the settings screen; and
11), on a programmable logic controller (PLC) panel, providing two settings parameters that are respectively each dynamic adjustment time (time01) and each dynamic adjustment opening degree 0P01 of the electric three-way regulating valve, wherein an upper limit of each dynamic adjustment time is set to 30 seconds, and an upper limit of each dynamic adjustment opening degree is set to 10%, to prevent a mis-operation.

A novel application of the integrated server cabinet allowing for waste heat recovery is provided, where the integrated server cabinet is applied to a plurality of occasions with a heat source need, and the occasions include but are not limited to the following:

heating: an apartment, a villa, a shopping mall, a restaurant, an office building, a venue, a theater, a factory, a warehouse, an agricultural greenhouse, fresh air preheating, and any other area with a heating need;

hot water: domestic hot water, swimming pool heating, fish pond heating, to meet a daily domestic water need; and

others: parts that require heat for drying, high-temperature sterilization, and steam generator preheating.

Compared with the prior art, the present disclosure has the following advantages and positive effects:
1. On the basis of an existing cabinet, in the present disclosure, waste heat utilization is performed on heat generated during an operation of the server to meet a heat supply need. The medium is transported to a heat using point through a water pump, the plate heat exchange component, and another device. Heat supply output is controlled by a three-way valve, a flow meter, a frequency converter, and another device. A total amount of heat supply is calculated through a heat meter to meet heat needs of different areas. An operation of a liquid cooling server, a heat exchange station for waste heat utilization, the server, and heating management are integrated, and therefore, a single cabinet of the present application has a small load, can operate in combination with another cabinet, and is high in integration and simple to mount.
2. A modular structure is adopted in the present disclosure, and the cabinet is mainly divided into upper and lower portions to separate an electrical part from a waste heat utilization module, and therefore, a safe operation in a server area is ensured and stability of data protection is improved. A modular design is adopted for the cooling distribution unit on the lower portion to form the skid-mounted structure that can be directly replaced to cope with different types of server integration, and therefore, rapid disassembly and reassembly are achieved, repair and maintenance are convenient, and costs of relocation are reduced. An on-site installation process is simplified through a bult-in pump station, and therefore, immediate production after cables and pipelines are connected can be achieved.
3. A plate heat exchange unit may be disposed in the present disclosure as a heating unit, to achieve waste heat recovery and sufficiently recover heat dissipated by the server as a heat source of the plate heat exchange component. A heat-exchanged and cooled medium flows back into a central display unit (CDU) module, and a heated-up medium is output to meet heat supply and heating needs in different occasions, and therefore, a plurality of functions are integrated, and energy consumption is reduced because of heat recovery.
4. In the present application, due to integration of a plurality of functions and waste heat utilization, energy saving and high efficiency are achieved, and overall thermal efficiency is up to 97%. In this case, both server operation and heat needs are met through an energy source, and therefore, a low carbon emission is achieved, and dual carbon emissions of server operation and heat supply are changed into a single carbon emission. In addition, additional benefits can be generated, and server computing power benefits can be generated during heating.

### BRIEF DESCRIPTION OF THE DRAWINGS

The accompanying drawings which constitute a part of the description of the present disclosure are intended to provide further understanding of the present disclosure. The exemplary embodiments of the present disclosure and descriptions thereof are intended to be illustrative of the present disclosure and do not constitute an undue limitation of the present disclosure. In the accompanying drawings:

FIG. 1 is a control logic diagram in which a server is RACKCAB according to an implementation of the present disclosure;

FIG. 2 is a control logic diagram in which a server is HYDROCAB according to an implementation of the present disclosure;

FIG. 3 is a logic diagram of a primary-circulation flow rate control system according to the present disclosure;

FIG. 4 is a logic diagram of a primary-circulation temperature control system in a common mode according to the present disclosure;

FIG. 5 is a logic diagram of a primary-circulation temperature control system in a waste heat utilization according to the present disclosure;

FIG. 6 is a logic diagram of a secondary-circulation temperature control system in a climate compensation mode according to the present disclosure;

FIG. 7 is a logic diagram of a secondary-circulation temperature control system-a tail temperature control logic diagram according to the present disclosure;

FIG. 8 is a logic diagram of a secondary-circulation temperature control system-a circulation water temperature control logic diagram according to the present disclosure;

FIG. 9 is a table showing initial letters of alphabetic symbols and descriptions thereof according to the present disclosure;

FIG. 10 is a structural schematic diagram in which a server is RACKCAB and there is no rear view of a cabinet body according to an implementation of the present disclosure;

FIG. 11 is a structural schematic diagram in which a server is RACKCAB and there is no side view of a cabinet body according to an implementation of the present disclosure;

FIG. 12 is a structural schematic diagram in which a server is HYDROCAB and there is no rear view of a cabinet body according to an implementation of the present disclosure; and

FIG. 13 is a structural schematic diagram in which a server is HYDROCAB and there is no bottom view of a cabinet body according to an implementation of the present disclosure.

### DESCRIPTION OF REFERENCE NUMERALS

1: server; 2: primary-circulation master water inlet pipeline; 3, primary-circulation master water return pipeline; 5: cold water inlet of a primary circulation pipeline; 6: hot water return opening of the primary-circulation pipeline; 7: hot water outlet of a secondary circulation pipeline; 8: cold water return opening of the secondary-circulation pipeline; and 9: plate heat exchange component.

### DETAILED DESCRIPTION OF THE EMBODIMENTS

It should be noted that embodiments in the present disclosure or features in the embodiments may be combined with one another without conflict.

It should be understood that in the description of the present disclosure, terms such as “central”, “longitudinal”, “transverse” “upper”, “lower”, “front”, “rear”, “left”, “right” “vertical”, “horizontal”, “top”, “bottom”, “inside” and “outside” indicate the orientation or position relationships based on the drawings, are merely intended to facilitate and simplify the description of the present disclosure, rather than to indicate or imply that the mentioned device or components must have a specific orientation or must be constructed and operated in a specific orientation. Therefore, these terms should not be construed as a limitation to the present disclosure. Moreover, terms such as “first” and 37 second” are used only for the purpose of description and cannot be understood as indicating or implying relative importance or implicitly indicating a number of technical features denoted. Thus, features defined with “first” and 37 second” may explicitly or implicitly include one or more of the features. In the description of the present disclosure, unless otherwise specified, “a plurality of” means two or more.

In the description of the present disclosure, it should be noted that, unless otherwise clearly specified, meanings of terms “mount”, “connected with”, and “connected to” should be understood in a board sense. For example, the connection may be a fixed connection, a removable connection, or an integral connection; may be a mechanical connection or an electrical connection; may be a direct connection or an indirect connection by using an intermediate medium; or may be intercommunication between two elements. A person of ordinary skill in the art may understand specific meanings of the above terms in the present disclosure based on a specific situation.

The specific embodiments of the present disclosure are described in detail below with reference to the accompanying drawings.

A working principle of a dry cooler is mainly based on a heat exchange principle. Specifically, a circulating refrigerant inside the dry cooler flows in pipelines, and the pipelines are generally designed as efficient heat dissipation structures. When a high-temperature refrigerant flows through the pipelines, air is blown through surfaces of the pipelines through a fan outside the pipelines or natural air, to form heat exchange. In the process, the refrigerant passes through a pipe wall to transfer heat to outside air, making a temperature of the refrigerant decrease, and achieving a cooling effect. Outside air is heated due to absorption of heat of the refrigerant, and then is discharged or naturally dispersed. The heat exchange process is continuously performed, and the refrigerant flows in the dry cooler in a circulating manner, and heat is continuously released, keeping a temperature of the refrigerant at a low level. Therefore, a temperature of a liquid can be effectively reduced through the dry cooler, to achieve a cooling purpose. It should be noted that, in a working process of the dry cooler, no water is consumed, and therefore, water saving of the dry cooler is very obvious. In addition, heat exchange is performed by using air, and therefore, water mists or water drops are not generated during operation of the dry cooler, and the dry cooler can also be applied in an environment with a high requirement for humidity. In general, the dry cooler is configured to achieve a cooling effect by using a temperature difference between air and the refrigerant according to the heat exchange principle, and is an efficient and energy-saving device.

A plate heat exchange component, which is an efficient heat exchange component formed by a series of stacked metal sheets having a certain corrugated shape, is formed by stacking and holding down a plurality of stamped corrugated sheets using a frame and hold-down screws at certain intervals with a gasket disposed therearound for sealing. Holes at four corners of the sheets and the gasket form a distribution pipe and a collection pipe for a fluid. Meanwhile, cold and hot fluids are separated reasonably and allowed to flow in flow channels on two sides of each sheet, respectively. Heat exchange is achieved through the sheets. Thin rectangular channels are formed between various sheets, and heat exchange is achieved through the sheets. The plate heat exchange component is an and liquid-steam heat exchange. The plate heat exchange component is high in heat exchange efficiency, low in heat loss, compact and light in structure, small in floor area, wide in application, and long in service life.

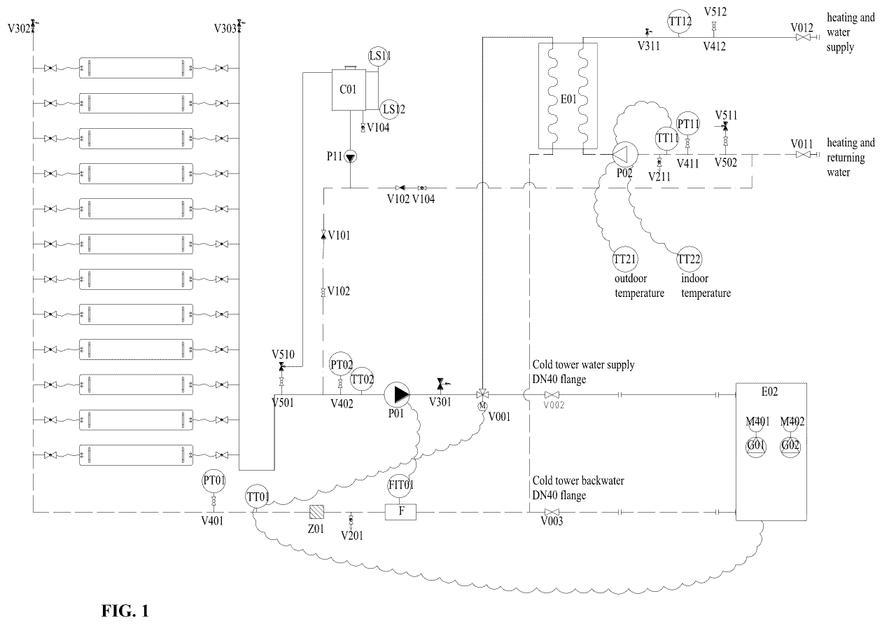

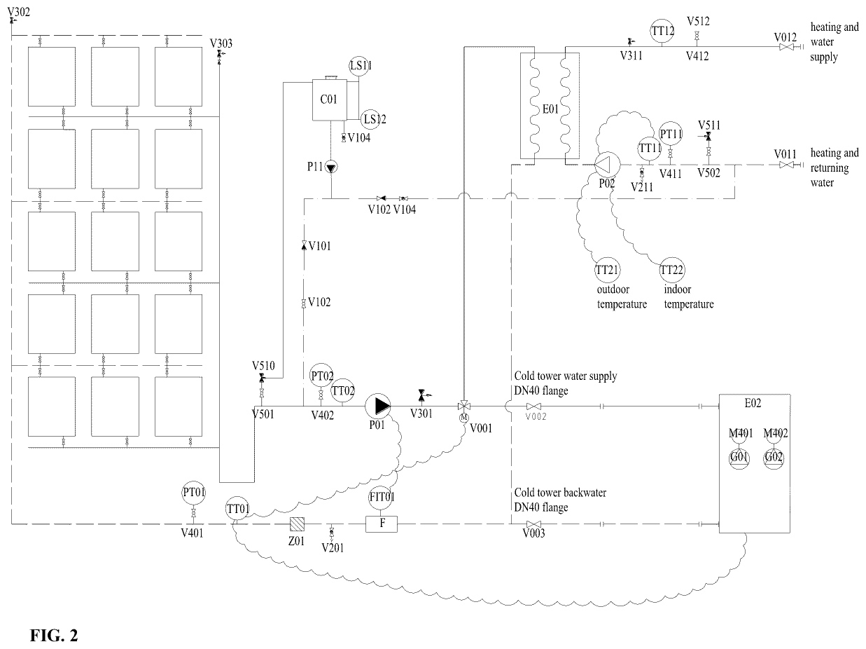

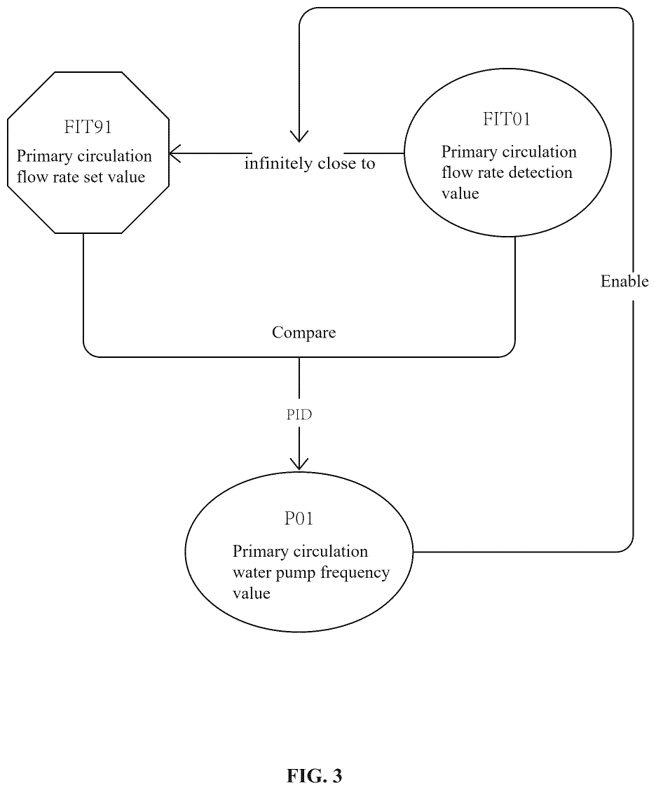

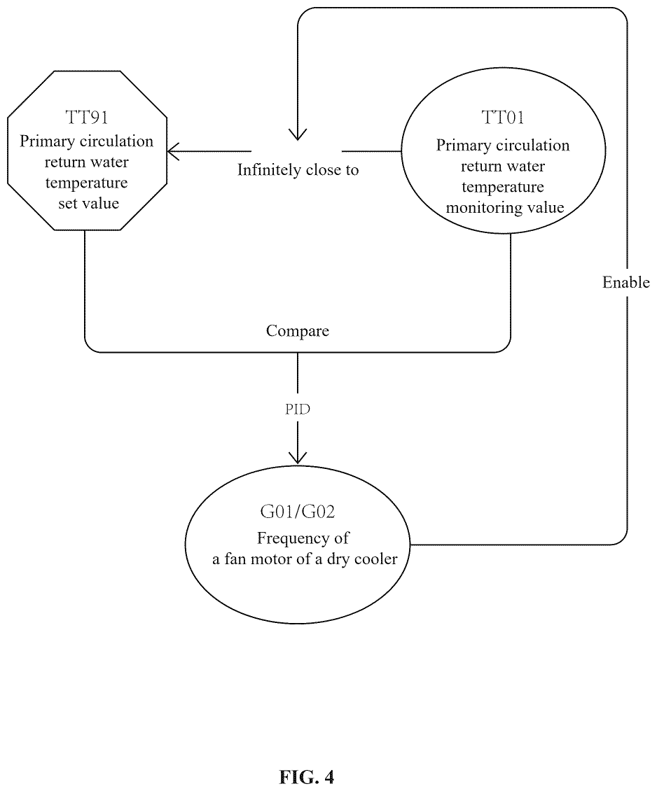

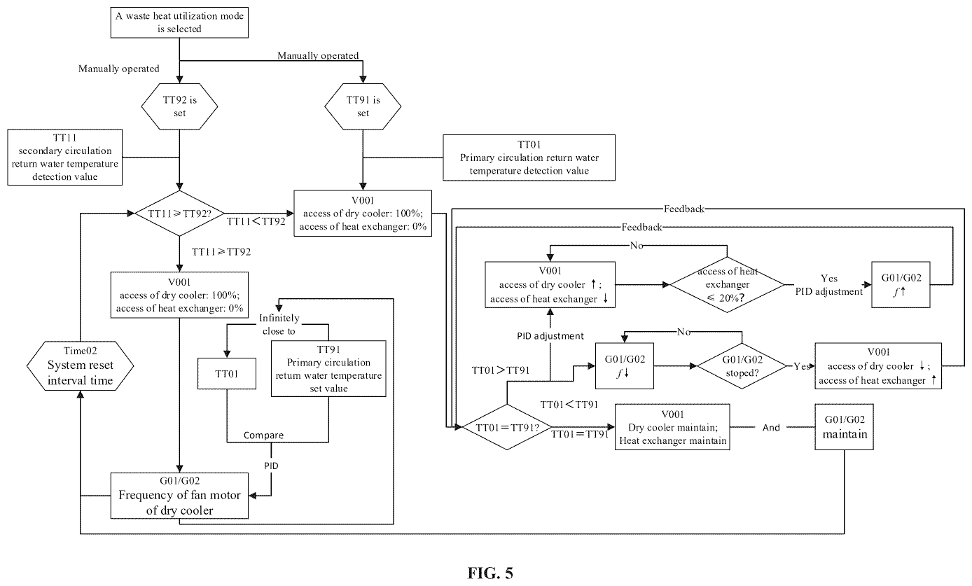

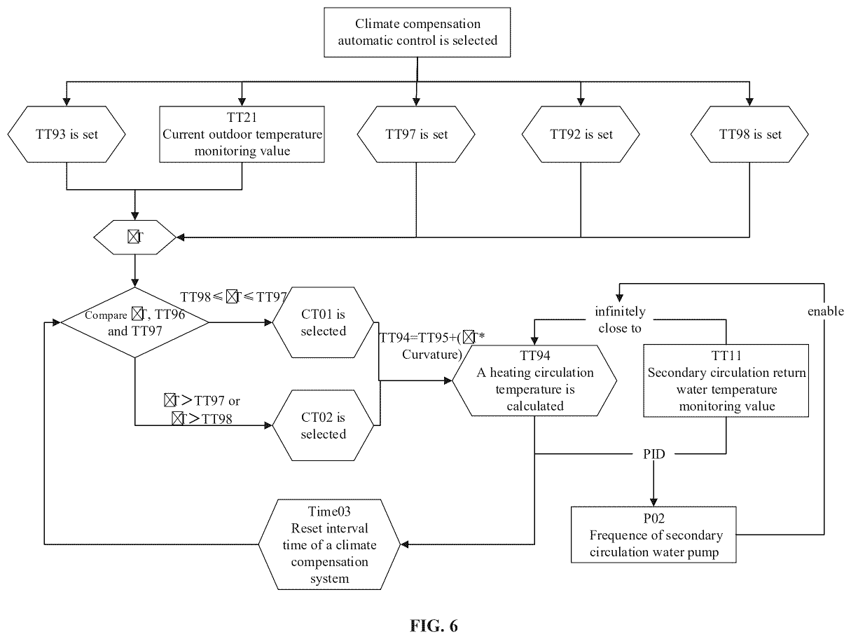

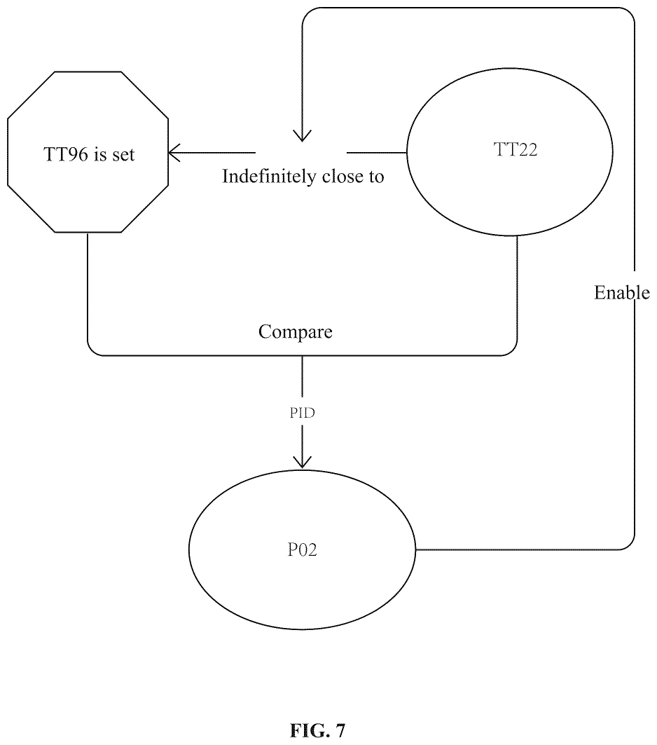

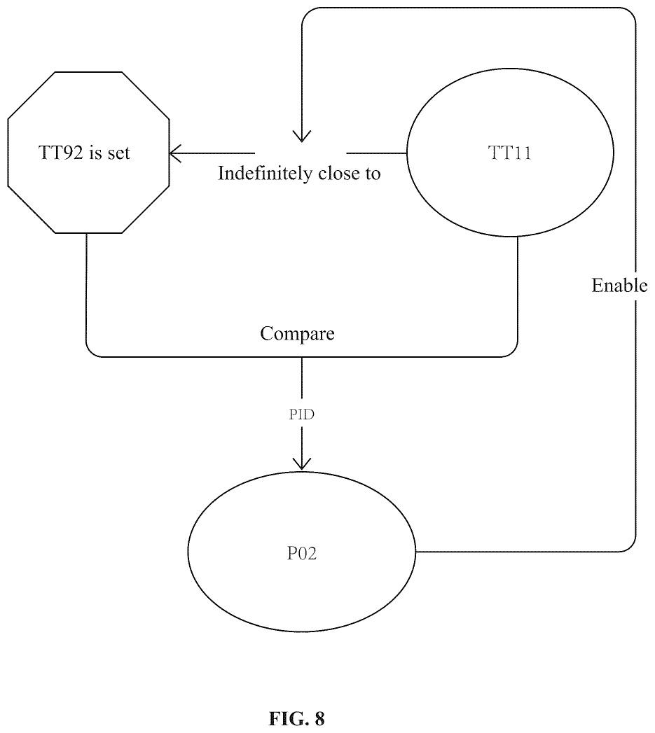

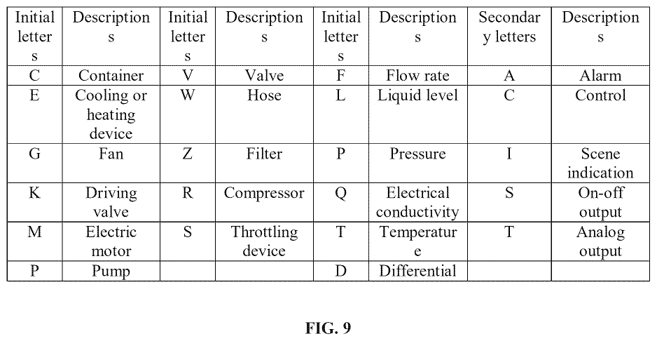

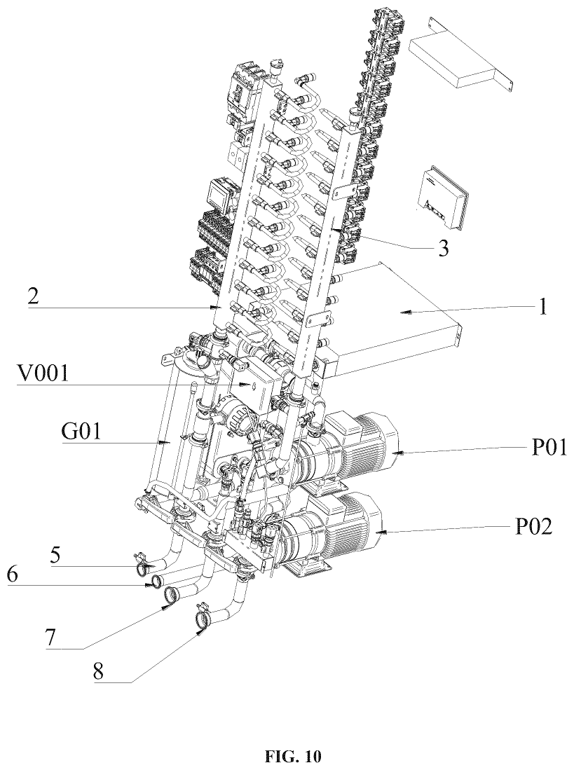

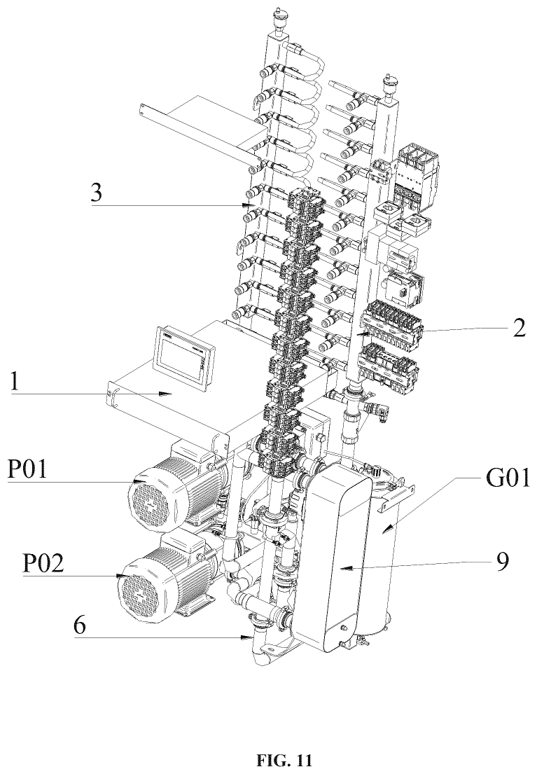

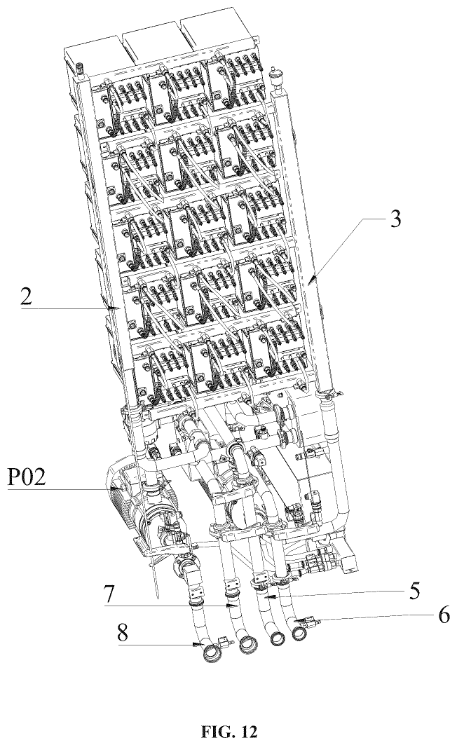

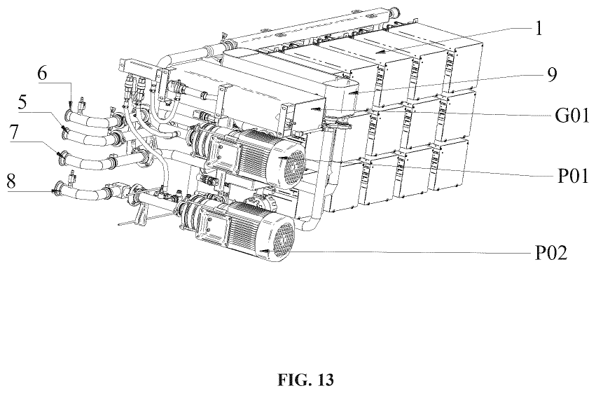

As shown in FIG. 1 to FIG. 13, the present disclosure provides an integrated server cabinet allowing for waste heat recovery and a control method. For a cabinet type liquid cooling system, an appropriate working environment is provided for a liquid cooling server, to ensure that the liquid cooling server stably works in a good working condition. In a conventional liquid cooling server cycle, a cooling source is connected to dissipate heat into atmosphere, and the integrated server cabinet can be configured to: perform waste heat recovery on heat generated during operation of a server, convey a medium to a heat using point through a water pump, a plate heat exchange component or another device, control heating output through a three-way valve, a flow meter, a frequency converter, or another device, and count a total amount of heat supply through a heat meter.

The integrated server cabinet allowing for waste heat recovery is mainly used in an independent cabinet structure with a data volume less than 100K, and includes a plurality of servers 1, a cooling distribution unit, and a control component, where the plurality of servers may be placed on units in a plurality of rows and columns.

The cooling distribution unit (CDU) includes a primary circulation pipeline. A waste heat utilization module includes a secondary circulation pipeline. The primary circulation pipeline and the secondary circulation pipeline are configured to adjust water flow rates in the primary circulation pipeline and the secondary circulation pipeline through an electric three-way regulating valve, to allow a whole system to switch among a primary temperature control mode, a waste heat utilization mode, and a secondary temperature control mode. The primary circulation pipeline serves as a cooling source and is configured to cool and dissipate heat for the plurality of servers through medium circulation.

The secondary circulation pipeline is used as a bypass branch of a liquid cooling system, and is configured to perform waste heat recovery, to provide heat supply to an external component with a heat source need.

A plate heat exchange component is further included, where a medium that is heated up by the server and that is in the primary circulation pipeline is used as heat source supply of the plate heat exchange component, and after being heat-exchanged by the plate heat exchange component, a part of a cooled medium flows back into the primary circulation pipeline, and another part of a heated-up medium is used as a supply source of a heat source in the secondary circulation pipeline. In the present application, the plate heat exchange component is adopted. For example, the technical solution of the present application also can be implemented by another structure capable of achieving medium heat exchange on the market in consideration of factors of costs and mounting space within a protection range of the present application.

More preferably, the structure in the present application is of a cabinet type structure, and includes a cabinet body that is of a highly-integrated structure and is divided into upper and lower portions. The plurality of servers are located on the upper portion. A length and a width of the cooling distribution unit are equal to a length and a width of the cabinet, and a height of the cooling distribution unit is reduced as much as possible, to reserve space for a layout of the servers. The cooling distribution unit is disposed on the lower portion, and is assembled into a skid-mounted structure, to facilitate fast disassembly and assembly.

The primary circulation pipeline is disposed on a back surface of the cabinet in a reversed return layout, and a flexible connection for preventing an operation of the server from being affected by vibration of the CDU is disposed between the pipeline and the CDU. The control component is mainly an electrical component, is disposed on an upper portion of a front surface of the cabinet body, is isolated and partitioned away from the pipeline and the CDU, and mainly includes a master switch, a branch switch, a frequency converter, a programmable logic controller (PLC) module, a screen, a wiring terminal, a cable, and a copper bar.

The structural layout in the present application follows a principle of proximity and a principle of mutual non-interference. The principle of proximity is to reduce interfaces, cables, pipelines, and the like as much as possible, and related parts should be attached to each other. The principle of mutual non-interference is to reduce or avoid crossovers between partitions as much as possible. On the basis of the above, detailed partitions are achieved to determine limit space of each part, and finally, a highly-integrated cabinet is formed according to arrangement and combination of the limit spaces. Then, in a partitioned design, the server, the control component, the primary circulation pipeline, and the secondary circulation pipeline are separately designed in partitions, and are finally assembled and combined and adjusted; and all partitions are assembled according to an initial plan, and are adjusted by checking interference and a rationality condition.

In a structural layout process, a final size of the cabinet body needs to be obtained through parameter calculation according to the following detail calculation steps.

In S1, a total power of the plurality of servers is determined, and rounding is performed after an amplification coefficient is calculated according to the total power to determine a heat exchange power of the CDU.

In S2, a flow rate of a primary circulation pump is calculated, where a primary circulation temperature difference Δt is obtained according to a difference between an ultimate inlet water temperature and an ultimate outlet water temperature of the server, and the flow rate of the primary circulation pump is calculated according to the following formulas:

$$Q = cm Δ t ;$$

$$Q = c ( ρ V ) Δ t ;$$

$$V = Q / ( c ρΔ t ) .$$

In the foregoing formulas, characteristic of a cooling medium include a freezing point, a boiling point, a density, and a specific heat capacity, where C represents the specific heat capacity, and represents a capability of heat required to increase a temperature of a material, the unit of the specific heat capacity is Joule per Kilogram-Celsius; m represents a mass of an object, Δt represents an amount of temperature change, namely, an increased (or a decreased) temperature of the object; p: represents a density of a material, and represents a ratio of a material mass to a volume, measured in kilogram per cubic meter; and V represents a volume of a material, measured in cubic meter.

The flow rate is determined by finally setting the amplification coefficient.

In S3, a lift of the primary circulation pump is calculated, a pipeline specification is selected, and a specific frictional resistance of a pipeline is determined according to the selected pipeline specification, where

a calculation formula for a pipeline resistance loss is ΔP=L·Δp.

L is equal to a sum of a length of the pipeline, a length of an elbow, a length of a tee joint, a length of a valve group, a length of the plate heat exchange component, and a length of the server, namely, an equivalent length of a most unfavorable loop for primary circulation;

Δp represents the specific frictional resistance of the pipeline, and the lift of the primary circulation pump is greater than Δp.

In S4, a flow path and a lift of a secondary circulation pump are calculated, where a calculation process is same as a calculation process of the primary circulation pump, and a difference lies in that L is equal to a sum of the length of the pipeline, the length of the elbow, the length of the valve group, the length of the plate heat exchange component, and a length of a heating end, namely, an equivalent length of a most unfavorable loop for secondary circulation.

In S5, plate heat exchange component model selection is performed, where a power of the plate heat exchange component is consistent with a power sum of the plurality of servers, and the power sum of the plurality of servers is approximately a sum of powers of the plurality of servers; and then a heat exchange area is calculated by performing the plate heat exchange component model selection according to a difference between a primary supply water temperature and a primary return water temperature, and a difference between a secondary supply water temperature and a secondary return water temperature.

In S6, model selection of the pipeline, a pipe fitting, and the valve group is determined, where a pipeline with an optimal specific frictional head loss is selected by rounding up the flow rates in the primary circulation pipeline and the secondary circulation pipeline into an integer, and a square pipe is selected as a vertical pipe, thus utilizing space more effectively while marking specific frictional resistances of the pipeline and the vertical pipe be close to each other; and a same pipe diameter is selected for the pipe fitting and the valve group.

After the calculation is completed, the structural layout needs to be performed to make the length and the width of the CDU be equal to the length and the width of the cabinet, and reduce the height as much as possible, to reverse space for laying out the servers. If the electric three-way regulating valve is mounted at a water inlet of the plate heat exchange component, the electric three-way regulating value is diverged; or if the electric three-way regulating valve is mounted at a water outlet of the plate heat exchange component, the electric three-way regulating valve is converged.

A structural layout for RACKCAB in Embodiment 1 is as follows: The primary circulation pump and the secondary circulation pump are disposed in parallel up and down, and are disposed at a side of the cabinet body, the primary circulation pump is located at an upper end of the secondary circulation pump, the fan of the dry cooler and the plate heat exchange component are vertically disposed in parallel on a same side, and are located on a side that is of the cabinet body and that is away from the primary circulation pump; and after the primary circulation pump and the secondary circulation pump are disposed away from each other up and down, occupied total space of an up-down height is not greater than a total height of the plate heat exchange component or the fan of the dry cooler, and a middle position between two sides is provided with a pipeline.

The water inlet end and the water outlet end are horizontally placed in a centralized manner and are disposed in parallel, and are located at a lowest end of a CDU structure. From left to right, there are sequentially a cold water inlet 5 of the primary circulation pipeline, a hot water return opening 6 of the primary circulation pipeline, a hot water outlet 7 of the secondary circulation pipeline, and a cold water return opening 8 of the secondary circulation pipeline. In this way, a primary circulation pipeline path is formed. A cooling medium enters the primary circulation pipeline through the cold water inlet of the primary circulation pipeline to cool the plurality of servers, after being heated up, the heated-up medium passes through the electric three-way regulating valve, a part of the heated-up medium enters the plate heat exchange component, and another part of the heated-up medium flows back into the fan of the dry cooler through the three-way valve. In this way, the primary circulation pipeline is formed. The secondary circulation pipeline: The heated-up medium entering the plate heat exchange component is heat-exchanged, the heated-up medium is output by the plate heat exchange component and enters the secondary circulation pipeline as heat source supply, achieving waste heat recovery. In the reutilization process, the medium in the secondary circulation pipeline is cooled, flows back into the plate heat exchange component through the secondary circulation pump to be heat-exchanged again, and waste heat is partially utilized. In this way, the secondary circulation pipeline is formed. Further, an upper end of the plate heat exchange component is connected to the hot water return opening of the primary circulation pipeline and the hot water outlet of the secondary circulation pipeline, a lower end of the plate heat exchange component is connected to the cold water inlet of the primary circulation pipeline, and the cold water return opening of the secondary circulation pipeline, a heat source inlet and a heat source outlet are provided at the upper end, and a lower-temperature inlet and a low-temperature outlet are provided at the lower end. In this way, a heat exchange need of a maximum path and high heat exchange efficiency are achieved.

A structural layout for HYDROCAB in Embodiment 2 is as follows: The primary circulation pump and the secondary circulation pump are disposed left and right in parallel, and are located at a side of the cabinet body. The fan of the dry cooler is transversely disposed, and a center line in a length direction of the fan of the dry cooler and an axis of the primary circulation pump are disposed in parallel. The plate heat exchange component is disposed at an upper end of the fan of the dry cooler, and the plate heat exchange component and the fan of the dry cooler are disposed at a side of the cabinet body in the length direction. A tail end of the primary circulation pump and a tail end of the secondary circulation pump are disposed close to a rear end of the cabinet body. The side surface of the plate heat exchange component and the front end of the cabinet body are configured to lay pipelines.

The water inlet end and the water outlet end are horizontally placed in a centralized manner and are disposed in parallel, and are located at a lowest end of a CDU structure. From left to right, there are sequentially a cold water return opening of the secondary circulation pipeline, a hot water outlet of the secondary circulation pipeline, a cold water inlet of the primary circulation pipeline, and a hot water return opening of the primary circulation pipeline. In this way, a primary circulation pipeline path is formed. A cooling medium enters the primary circulation pipeline through the cold water inlet of the primary circulation pipeline to cool the plurality of servers, after being heated up, the heated-up medium enters the electric three-way regulating valve to be heat-exchanged as heat source supply. After being heat-exchanged, a heat-exchanged high-temperature medium passes through the electric three-way regulating valve, a part of the heated-up medium enters the plate heat exchange component, and another part of the heated-up medium flows back into the fan of the dry cooler through the three-way valve. In this way, the primary circulation pipeline is formed. The secondary circulation pipeline: The heated-up medium entering the plate heat exchange component is heat-exchanged, the heated-up medium is output by the plate heat exchange component and enters the secondary circulation pipeline as heat source supply, achieving waste heat recovery. In the reutilization process, the medium in the secondary circulation pipeline is cooled, flows back into the plate heat exchange component through the secondary circulation pump to be heat-exchanged again, and waste heat is partially utilized. In this way, the secondary circulation pipeline is formed. Further, a front end that is of the plate heat exchange component and that is close to the cabinet is connected to the hot water return opening of the primary circulation pipeline and the hot water outlet of the secondary circulation pipeline, a rear end of the plate heat exchange component is connected to the cold water inlet of the primary circulation pipeline, and the cold water return opening of the secondary circulation pipeline, a heat source inlet and a heat source outlet are provided at the upper end, and a lower-temperature inlet and a low-temperature outlet are provided at the lower end. In this way, a heat exchange need of a maximum path and high heat exchange efficiency are achieved.

More preferably, the cabinet body is of a framework structure, is internally provided with the plurality of servers, and a seam is provided between adjacent servers for laying the primary circulation pipeline. The primary circulation pipeline includes but is not limited to the fan of the dry cooler. Alternatively, another liquid cooling type server is used provided that a cooling medium supply source can be provided. The primary circulation pipeline further includes a primary-circulation master water inlet pipeline 2 and a primary-circulation master water return pipeline 3, one server corresponds to one water inlet branch and one water outlet branch. The primary-circulation master water inlet pipeline is simultaneously accessed into cooling areas of the plurality of servers through a plurality of water inlet branches, and then is returned to the primary-circulation master water return pipeline through water outlet branches. A valve for controlling on and off of water flow is separately disposed on each water inlet branch and each water outlet branch. Opening and closing of each valve can be determined and adjusted according to a number of servers that are actually placed in the cabinet body, to meet cooling needs of servers of different scales. In this way, efficient cooling can be achieved in a targeted manner, and unnecessary energy consumption waste is avoided.

It should be noted that, the cooling medium in the present application is water or another cooling medium, and is not specifically limited provided that a cooling need is met. The water outlet and the like described in the present application may be a liquid outlet end, and water is an implementation.

More preferably, from the fan of the dry cooler to the server, the primary-circulation master water inlet pipeline is sequentially provided with a first valve V003, a primary water circulation flow meter FIT01, and a primary inlet water temperature signal meter TT01. From the server to the fan of the dry cooler, the primary-circulation master water return pipeline is sequentially provided with a primary return water temperature signal meter TT02, a primary circulation water pump P01, an electric three-way regulating valve V001, and a second valve V002. The primary water circulation flow meter FIT01 is configured to feed back a signal to the control component. The control component is configured to: compare a fed-back value of the primary water circulation flow meter FIT01 with a set target flow rate through a proportion integration differentiation (PID) algorithm module and adjust a frequency of the primary circulation water pump, making a value of the primary water circulation flow meter FIT01 be close to a set target flow rate.

One way of the electric three-way regulating valve V001 is connected to one secondary circulation water inlet pipe of the secondary circulation pipeline. The secondary circulation pipeline further includes a plate heat exchange component, and a water inlet end of the plate heat exchange component includes two inputs, one input is one secondary circulation water inlet pipe connected to the electric three-way regulating valve V001, and is used as a heat-exchange heat source, and the other input is a water source supply pipe connected to the outside, is a cooled water source after waste heat utilization, that is, a medium in the secondary circulation pipeline flows back into the plate heat exchange component after being circulated and cooled. Hot water is supplied to the outside through further heat exchange. A secondary circulation water pump P02 and a secondary return water temperature signal meter TT11 are disposed on the secondary-circulation water inlet master pipe. The secondary return water temperature signal meter TT11 is configured to feed back a signal to the control component. In addition, an outdoor temperature signal meter TT21 and an indoor temperature signal meter TT22 configured to measure a temperature in a heat supply room are disposed. Both the outdoor temperature signal meter TT21 and the indoor temperature signal meter TT22 are electrically connected to the control component, and are configured to feed back a real-time temperature to the control component. The water outlet end of the plate heat exchange component is also divided into two branches, one branch is configured to return a cooled medium to the primary-circulation master water inlet pipeline in the primary circulation pipeline, and is connected between the first valve V003 and a primary water circulation flow meter FIT01. The other branch is connected to an external component with a heat source need. Waste heat utilization can be applied to a plurality of fields. Details are as follows.

Heating: an apartment, a villa, a shopping mall, a restaurant, an office building, a venue, a theater, a factory, a warehouse, an agricultural greenhouse, fresh air preheating, and any other area with a heating need, these areas are mostly personnel gathering areas with specific requirements on heating. In a current social environment, a big data processing amount in the personnel gathering areas is large, and a server cabinet is probably disposed. Waste heat recovery can be performed again by using the technical solution in the present application.

Hot water: domestic hot water, swimming pool heating, fish pond heating, to meet a daily domestic water need.

Others: parts that require heat for drying, high-temperature sterilization, and steam generator preheating.

More preferably, when heat source supply of the primary circulation pipeline cannot meet a heat recovery need, a heat source supply pipe connected to the outside can be used as a supplement. In this way, entire heat recovery is performed well, to meet a use need. Certainly, an external heat source is disposed in the structure in the present application, and heat of the server is sufficiently recovered, and therefore, environment friendliness is achieved.

Before steps of different control methods are described, each signal or numeric code is firstly described in the following table.

| Descriptions of | | | |
|---|---|---|---|
| signal points in | Descriptions of | Descriptions of set | Descriptions of |
| control | control points | values | calculated values |
| TT01: primary inlet | P01: primary | FIT91: primary water | TT94: calculated |
| water temperature | circulation | flow rate set value | circulation |
| TT02: primary | water pump | TT91: primary return | temperature |
| return water | P02: secondary | water temperature set | ΔT: difference |
| temperature | circulation | value | between TT21 |
| TT11: secondary | water pump | TT92: secondary return | and TT93 |
| return water | V001: electric | water temperature set | |
| temperature | three-way | value | |
| TT21: outdoor | regulating valve | TT93: standard outdoor | |
| temperature | G01/G02: fan of | temperature | |
| TT22: indoor | a dry cooler | TT95: standard | |
| temperature (inside | | circulation temperature | |
| a heat supply room) | | CT01: curvature 1 | |
| FIT01: primary | | CT02: curvature 2 | |
| water circulation | | TT96: target indoor | |
| flow rate (flow | | temperature (inside a | |
| meter) | | heat supply room) | |
| | | TT97: positive value of | |
| | | a curvature selection | |
| | | interval | |
| | | TT98: negative value of | |
| | | a curvature selection | |
| | | interval | |
| | | Time01: adjustment | |
| | | cycle time of a | |
| | | three-way valve | |
| | | OP01: dynamic | |
| | | adjustment opening | |
| | | degree of a three-way | |
| | | valve | |
| | | Time02: reset time of a | |
| | | waste heat utilization | |
| | | temperature-control | |
| | | system | |
| | | Time03: reset time of a | |
| | | climate compensation | |
| | | system | |

A primary flow rate control method is as follows:

A target flow rate value FIT91 is manually set, and the value needs to be displayed on a settings screen.

The value of FIT91 is compared with the value of FIT01, and frequency adjustment is performed on the primary circulation water pump P01 through the PID algorithm module, making FIT01 be infinitely close to FIT91.

### a Primary Return Water Temperature Control Method is as Follows:

The target primary return water temperature TT91 is set; and opening degree and rotation speed adjustment is performed on V001 and G01/G02 through the PID algorithm module; and TT01 is made be close to TT91.

Details are as follows: The target primary temperature value TT91 is manually set with a tolerance of (+2° C.), and the value and a range value need to be displayed on the settings screen.

An access of the dry cooler of the electric three-way regulating valve V001 is set to 100%, and an access of the plate heat exchange component is set to 0%.

The value of TT91 is compared with the value of TT01, and frequency adjustment is performed on G01/G02 through the PID algorithm module, and TT01 is made be infinitely close to TT91.

### a Waste Heat Utilization Mode Control Method is as Follows:

A target primary return water temperature TT91 and a target secondary return water temperature TT92 are set; TT92 is compared with TT11 to determine whether waste heat utilization is needed; opening degree and rotation speed adjustment is performed on V001 and G01/G02 through the PID algorithm module; TT01 is made be close to TT91; and the first step is returned after stabilization for a period of time to readjust. Details are as follows.
(1). The target primary temperature value TT91 is manually set with a tolerance of +2° C., where the value and a range value need to be displayed on a settings screen; and the target secondary temperature value TT92 is manually set with a tolerance of +2° C., where the value and a range value need to be displayed on the settings screen.
(2). The value of TT11 is compared with the value of TT92, (3) is performed if TT11>TT92; or performing (5) is performed if TT11<TT92.
(3). An access of a dry cooler of an electric three-way regulating valve V001 is set to 100%, an access of a plate heat exchange component is set to 0%, the value of TT91 is compared with the value of TT01, frequency adjustment is performed on G01/G02 through the PID algorithm module, and TT01 is made be infinitely close to TT91.
(4). A time interval time02 is set, counting starts to be performed for time02 after heat supply balance is achieved, and a system is made automatically return to (2) to readjust after counting is ended, where a readjustment time interval needs to be displayed on the settings screen.
(5). The access of the dry cooler of the electric three-way regulating valve V001 is set to 0%, and the access of the plate heat exchange component is set to 100%.
(6). The value of TT01 is compared with the value of TT91, (7) is performed if TT01>TT91; or (8) is performed if TT01<TT91; or (9) is performed if TT01=TT91.
(7). The access of the dry cooler is slowly increased and the access of the plate heat exchange component is slowly decreased, and when an opening degree of the access of the plate heat exchange component is less than or equal to 20%, a rotation speed of a fan G01/G02 of the dry cooler is adjusted to slowly increase through the PID algorithm module until an effect of TT01=TT91 is achieved in step (9).
(8). The rotation speed of the fan G01/G02 of the dry cooler is adjusted to slowly decrease through the PID algorithm module, and after the fan of the dry cooler is stopped, the access of the dry cooler is slowly decreased and the access of the plate heat exchange component is slowly increased until the effect of TT01=TT91 is achieved in step (9).
(9). A current opening degree of the electric valve V001 is kept and a current rotation speed of G01/02 is kept.
(10). A time interval time02 is set, counting starts to be performed for time02 after heat supply balance is achieved, and a system is made automatically return to (2) to readjust after counting is ended, where a readjustment time interval needs to be displayed on the settings screen.
(11). On a programmable logic controller (PLC) panel, two settings parameters that are respectively each dynamic adjustment time time01 and each dynamic adjustment opening degree 0P01 of the three-way valve are provided, where an upper limit of each dynamic adjustment time is set to 30 seconds, and an upper limit of each dynamic adjustment opening degree is set to 10%, to prevent a mis-operation.

### A Secondary Temperature Control Method, Namely, a Climate Compensation Automatic Control Method is as Follows:

A target secondary return water temperature TT94 is calculated according to an outdoor temperature TT21; frequency adjustment is performed on P02 through the PID algorithm module; TT11 is made be close to TT94; tail temperature control is performed; a target indoor temperature TT96 is set; frequency adjustment is performed on P02 through the PID algorithm module; TT22 is made be close to TT96; heat supply circulation water temperature control is performed; a target heat supply return water temperature TT92 is set; frequency adjustment is performed on P02 through the PID algorithm module; and TT11 is made be close to TT92. Details are as follows.
(1). A standard outdoor temperature TT93, a standard circulation temperature TT95, a compensation curvature 1CT01, a compensation curvature 2CT02, a curvature selection range partition value TT97/TT98, and system reset time time03 are set. All values are displayed on the screen and can be modified.
(2). A current outdoor temperature TT21 is measured by an outdoor temperature probe.
(3) ΔT is calculated, ΔT=TT93−TT21.
(4). It is determined which range ΔT belongs, (5) is performed if TT98° C.<ΔT≤TT97; or (6) is performed if ΔT>TT97 or ΔT<TT98.
(5). Calculation is performed by using CT01.
(6). Calculation is performed by using CT02.
(7). A circulation temperature TT94=TT95+ (ΔT×curvature) is calculated, and the value needs to be displayed on the screen.
(8). The circulation temperature TT94 is calculated as a target value of TT11.
(9). A rotation speed of a water pump is adjusted through the PID algorithm module, and a circulation flow rate is controlled, making a heat supply return water temperature TT11 be infinitely close to TT94.
(10). A time value time03 is set to measure an outdoor temperature per hour, so as to calculate a current circulation temperature TT94.

The foregoing three modes can be parallel, and are manually switchable.

The following provides a tail temperature control system.

A target indoor temperature value TT96 is manually set with a tolerance of (+2° C.), and the value and a range value need to be displayed on the screen.

The value of TT22 is compared with the value of TT96, and frequency adjustment is performed on P02 through the PID algorithm module, and TT22 is made be infinitely close to TT96.

Heat supply circulation water temperature control is as follows:

A target heat supply return water temperature value TT92 is manually set with a tolerance of (+2° C.), and the value and a range value need to be displayed on the screen. The value of TT11 is compared with the value of TT92, and frequency adjustment is performed on P02 through the PID algorithm module, and TT11 is made be infinitely close to TT92.

Embodiments are described below.

Outline dimension of the cabinet: The outline dimension of the cabinet is similar to of a common placing server cabinet, where width*depth*height=800*1000*2200 mm.

Server load: An upper half portion of the cabinet is occupied by 10-15 servers.

Cooling distribution unit (CDU): A length and a width of the cooling distribution unit are equal to those of the cabinet, and a height of the cooling distribution unit is reduced as much as possible, to reserve space for a layout of the servers. The cooling distribution unit is disposed on the lower half portion of the cabinet, and is assembled into a skid-mounted structure, to facilitate fast disassembly and assembly as a component, fast relocation and assembly, and integral replacement for repair and maintenance. Main devices include a primary circulation water pump, a secondary circulation water pump, a plate heat exchange component, a storage water tank, a water replenishment pump, a flow meter, an electric three-way regulating valve, a filter, a vale group, a pipeline, and the like.

The CDU is designed as follows:

### Heat Change Power

According to outline dimensions of the server and the cabinet, 12 units are designed for RACKCAB, and there are 15 units in total that occupy 1400 mm of upper space for RACKCAB, and powers of the servers are respectively 12*7.5=90 kW and 15*5.5=82.5 kW.

A heat exchange power of the CDU is determined as 100 kW by rounding after an amplification coefficient is calculated according to the power.

A difference between RACKCAB and HYDROCAB lies in that the RACKCAB server is in an up-down parallel layout, where water inlet ends are disposed on a same side, and water outlet ends are disposed on another side, and therefore, an overall left-inlet right-outlet structure is shown. The HYDROCAB server is an overall structure in which water flows in from the upper end and flows out from the lower end. No matter which structure of server is used, an independently controlled valve is disposed on each of a water inlet branch and a water outlet branch that are finally gathered onto a water inlet master pipeline and a water outlet master pipeline.

### Primary Circulation Water Pump

An ultimate water inlet/outlet temperature of the server is 45/55° C., and a primary circulation temperature difference Δt1=10° C. can be obtained.

A primary circulation medium of the server is pure water with physical properties as follows: a freezing point of 0° C., a boiling point of 100° C.,

a density of 999.84 kg/m³, and a specific heat capacity of 4.2 kJ/kg. K.

The data can be substituted into a heat calculation formula Q=cmΔt to obtain a flow rate of a primary circulation pump as follows:

$$Q = cm Δ t ;$$

$$Q = c ( ρ V ) Δ t ;$$

$$V = Q / ( c ρΔ t ) = 100 * 3600 / ( 4.2 * 1000 * 10 ) = 8.57 {m}^{3} / h .$$

The flow rate is obtained as 9.427 m³/h by calculating a 1.1-time amplification coefficient.

C represents the specific heat capacity, and represents a capability of heat required to increase a temperature of a material, the unit of the specific heat capacity is Joule per Kilogram-Celsius; m represents a mass of an object, Δt represents an amount of temperature change, namely, an increased (or a decreased) temperature of the object, where during heat absorption, Δt indicates a temperature increase value, and during heat release, Δt indicates a temperature decrease value. During heat absorption, Q=cmΔT increase (obtained by subtracting an initial temperature of the object from an actually increased temperature). During heat release, Q=cmΔT decrease (obtained by subtracting a decreased temperature from an actual initial temperature), or Q=cmΔT=cm (Tfinal−Tinitial), heat absorption is performed if Q>0, and heat release is performed if Q<0.

ρ: represents a density of a material, represents a ratio of a material mass to a volume, measured in kilogram per cubic meter; and v: represents a volume of a material, measured in cubic meter.

According to the “hydraulic calculation table for hot water pipelines”, it can be found that when selecting a DN50 pipeline for this flow rate, a pipeline resistance is about 713.9 Pa/m and a pipeline cross-sectional area is about 1900 mm². When selecting a DN65 pipeline, a pipeline resistance is about 128.3 Pa/m and a pipeline cross-sectional area is about 3300 mm².

Due to limited space inside the cabinet, most of the pipelines are selected as 40×40 mm square pipes with cross-sectional areas approximate to the cross-sectional area of the DN50 pipeline and a pipeline specific frictional resistance of 713.9 Pa/m.

Through a preliminary design, an equivalent length of a most unfavorable loop for primary circulation is a sum of a length of a pipeline, a length of an elbow, a length of a tee joint, a length of a valve group, a length of a plate heat exchange component, and a length of a server, that is, equal to 6 m+30 m+45 m+85 m+120 m+150 m=296 m.

The data is substituted into a calculation formula for a pipeline resistance loss as follows:

$$Δ P = L \cdot Δ p = 296 \times 713.9 = 211 , 314.4 Pa = 0.211 MPa .$$

The flow rate is obtained as 0.2311 MPa. by calculating a 1.1-time amplification coefficient.

Therefore, a lift of the primary circulation pump should be greater than 23 m to meet the need.

Through the foregoing calculation, parameters of the primary circulation water pump can be determined as follows:

Q=10 m³/h; and H=23 m.

### Calculation for the Secondary Circulation Water Pump is as Follows.

In a general heat supply design, a circulation temperature difference is 10° C. that is just in accordance with a difference between an inlet water temperature and an outlet water temperature of the server, and therefore, a secondary circulation temperature difference Δt2 is equal to 10° C.

The server needs to operate throughout the year and needs an outdoor cold source, and therefore, a medium inside the secondary pipeline is an ethylene glycol solution with a volume concentration of 50% that is taken as an anti-freezing measure. Physical properties of the solution are as follows: a freezing point of −37.9° C., a boiling point of 107.8° C., a density of 1063.66 kg/m³, and a specific heat capacity of 3.358 KJ/kg·K.

The data can be substituted into a heat calculation formula Q=cmΔt to obtain a flow rate of the secondary circulation pump as follows:

$$Q = cm Δ t ;$$

$$Q = c ( ρ V ) Δ t ;$$

$$V = Q / ( c ρΔ t ) = 100 * 3600 / ( 3.358 * 1063.66 * 10 ) = 10.0 \; 79 {m}^{3} / h .$$

The flow rate is obtained as 11.0869 m³/h by calculating a 1.1-time amplification coefficient.

As 4 or less than 4 devices are used in parallel, a total heat supply load will not exceed 400 kW. 400 kW can meet a heat supply need of about 8000 square meters at most, and an average pipeline specific friction is about 120 Pa/m. It is estimated that the equivalent length of a most unfavorable loop for the secondary circulation is equal to a sum of a length of pipeline, a length of an elbow, a length of a valve group, a length of a plate heat exchange component, and a length of heating end, that is, equal to 1000 m+500 m+200 m+120 m+500 m=2320 m.

The data is substituted into a calculation formula for a pipeline resistance loss as follows:

$$Δ P = L \cdot Δ p = 2320 \times 120 = 278 , 400 Pa = 0.278 MPa .$$

Therefore, a lift of the primary circulation pump should be greater than 30 m to meet the need.

Through the foregoing calculation, parameters of the primary circulation water pump can be determined as follows:

$$Q = 11 {m}^{3} / h ; and H = 30 m .$$

### Calculation for Parameters of a Water Replenishment Pump are as Follows.

According to calculation, a total water amount of the primary circulation system is about 300 L, and initial water replenishment time is designed to be 30 minutes. Therefore, a flow rate of the replenishment pump should not be less than 10 L/min.

A highest point of the server is about 2.2 m away from a water replenishment point, and a maximum pressure resistance of the server is about 3.5 bar, and therefore, a lift of the water replenishment pump should be between 2.5 m and 3.5m.

### Calculation for the Plate Heat Exchange Component is as Follows.

The heat exchange power has been confirmed to be 100 kW.

If a logarithmic temperature difference is set to 5° C., a heat-exchanged supply/return water temperature can also be confirmed by using the above calculation process:

A primary supply/return water temperature is 45/55° C., and a secondary supply/return water temperature is 40/50° C.

Calculation for plate heat exchange component model selection is performed according to the foregoing data to obtain:

a heat exchange area of 6.496 m², a primary circulation pressure drop of 38.6 kPa, and a secondary circulation pressure drop of 26.5 kPa.

For the calculation for the plate heat exchange component, refer to the existing model selection manual, or implementation of the calculation for the plate heat exchange component by using (application) APP for model selection on the market is a disclosed technical means. In the structure of the present application, the principle is also the same.

### a Pipeline, a Pipe Fitting, and a Valve Group are Determined as Follows.

Based on the above calculation results, flow rates in the primary circulation pipeline and the secondary circulation pipeline are rounded up into an integer as 11m 3/h. According to the “hydraulic calculation table for hot water pipelines”, it can be seen that a DN50 pipeline with an economic specific friction resistance should be selected, and a 40×40 mm square pipe should be selected as a vertical pipe. Space can be utilized more effectively when specific friction resistances of the DN50 pipeline and the vertical pipe are close to each other.

A same pipe diameter is selected for the valve and the pipeline.

A same pipe diameter is selected for the flow meter and the valve.

A same pipe diameter is selected for the electric three-way regulating valve. If the electric three-way regulating valve is mounted at a water inlet of the plate heat exchange component, a tee joint is diverged; or if the electric three-way regulating valve is mounted at a water outlet of the plate heat exchange component, the tee joint is converged.

Model selection for all devices can be completed through the foregoing calculation, and the devices are placed after outline dimensions of the devices are obtained.

Design principles include a principle of proximity, a principle of mutual non-interference, and a principle of disposing a wiring tube above a water pipe. The principle of proximity is to reduce pipelines, and elbows to reduce pipeline resistance. The principle of mutual non-interference is to make the device, the pipeline, and the valve group do not affect each other, to replace the device and the valve group conveniently, maintain and operate simply and conveniently, achieve high mounting feasibility, and the like. For safety, the principle of disposing a wiring tube above a water pipe is to prevent leakage accidents and avoid interlocking leakage accidents that may cause greater losses.

The structure in the present application may be configured to dispose liquid cooling servers (below 100 kW) on a small scale, that is, an integrated independent cabinet, and also may be configured to dispose liquid cooling servers on a large scale, that is, combined-cabinet operation. Waste heat utilization also can be used in a plurality of fields. Details are as follows.

Heating: an apartment, a villa, a shopping mall, a restaurant, an office building, a venue, a theater, a factory, a warehouse, an agricultural greenhouse, fresh air preheating, and any other area with a heating need, these areas are mostly personnel gathering areas with specific requirements on heating. In a current social environment, a big data processing amount in the personnel gathering areas is large, and a server cabinet is disposed. Waste heat recovery can be performed again by using the technical solution in the present application.

Hot water: domestic hot water, swimming pool heating, fish pond heating, to meet a daily domestic water need.

Others: parts that require heat for drying, high-temperature sterilization, and steam generator preheating.

In an application process, enterprises can meet needs of heating and daily hot water supply. Hot water supply is essential for many office areas or factories. Factories with production workshops or accommodation areas can meet the daily bathing needs of employees, especially in winter. In addition, water heating can be used for office heating, especially in areas where heating is inconvenient, and there is no additional energy consumption. Therefore, waste heat can be recovered sufficiently, and the environment is improved.

Compared with existing heating products in the market, including an electric boiler and a wall-mounted boiler, the integrated server cabinet in the present application has the following advantages.
1. Energy saving and high efficiency are achieved, and overall thermal efficiency is up to 97%. In this case, both server operation and heat needs are met through an energy source.
2. A low carbon emission is achieved, and dual carbon emissions of server operation and heating are changed into a single carbon emission.
3. Additional benefits are generated, and server computing power benefits can be generated during heating.
4. High integration and simple mounting are achieved, an on-site mounting procedure is simplified through a built-in pump station, and therefore, immediate production after cables and pipelines are connected can be achieved.

The foregoing is detailed description of one embodiment of the present disclosure, which is merely a preferred embodiment of the present disclosure and cannot be construed as limiting the scope of implementation of the present disclosure. Any equivalent modifications, improvements, etc. made within the application scope of the present disclosure should fall within the protection scope of the present disclosure.

What is claimed is:

1. An integrated server cabinet allowing for waste heat recovery, applied to a cabinet type liquid cooling system, and comprising a plurality of servers, a cooling distribution unit, a waste heat utilization module, a control component, and a plate heat exchange component, wherein
the cooling distribution unit comprises a primary circulation pipeline, the primary circulation pipeline serves as a cooling source and is configured to cool and dissipate heat for the plurality of servers through medium circulation;
the waste heat utilization module comprises a secondary circulation pipeline for waste heat recovery so as to provide heat supply to an external component with a heat source need, wherein the primary circulation pipeline and the secondary circulation pipeline are configured to adjust flow rates, in the primary circulation pipeline and the secondary circulation pipeline, of a heated-up medium on line through an electric three-way regulating valve, to allow a whole system to switch among a primary temperature control mode, a waste heat utilization mode, and a secondary temperature control mode; and
a medium that is heated up by the plurality of servers and that is in the primary circulation pipeline is used as heat source supply of the plate heat exchange component, and after being heat-exchanged by the plate heat exchange component, a part of the medium that is cooled flows back into the primary circulation pipeline, and a rest part of the medium that is heated up is used as a supply source of a heat source in the secondary circulation pipeline.

2. The integrated server cabinet according to claim 1, comprising a cabinet body, wherein a plurality of server stands are disposed in the cabinet body, the plurality of servers are placed on the server stands in a plurality of rows and columns, the cabinet body is divided into upper and lower portions, the upper portion is configured to place the plurality of servers, the lower portion is configured to place the cooling distribution unit and the plate heat exchange component, and is placed with a pipeline, a skid-mounted structure is formed by the cooling distribution unit, the primary circulation pipeline is disposed on a back surface of the cabinet in a reversed return layout, and a flexible connection for preventing the cooling distribution unit from vibrating is disposed between the primary circulation pipeline and the cooling distribution unit.

3. The integrated server cabinet according to claim 1, wherein the primary circulation pipeline comprises a primary circulation pump, a primary-circulation master water inlet pipeline, and a primary-circulation master water return pipeline, one server corresponds to one water inlet branch and one water outlet branch, the primary-circulation master water inlet pipeline is accessed into cooling areas of the plurality of servers through a plurality of water inlet branches, and then is returned to the primary-circulation master water return pipeline through water outlet branches, and a valve for controlling on and off of water flow is separately disposed on each water inlet branch and each water outlet branch; and
from a fan of a dry cooler to the server, the primary-circulation master water inlet pipeline is sequentially provided with a first valve, a primary water circulation flow meter (FIT01), and a primary inlet water temperature signal meter (TT01); from the server to the fan of the dry cooler, the primary-circulation master water return pipeline is sequentially provided with a primary return water temperature signal meter (TT02), a primary circulation water pump (PO1), an electric three-way regulating valve (V001), and a second valve (V002); the primary water circulation flow meter (FIT01) is configured to feed back a signal to the control component; and the control component is configured to: compare a fed-back value of the primary water circulation flow meter (FIT01) with a set target flow rate through a proportion integration differentiation (PID) algorithm module and adjust a frequency of the primary circulation water pump, making a value of the primary water circulation flow meter (FIT01) be close to the set target flow rate.

4. The integrated server cabinet according to claim 1, wherein the secondary circulation pipeline comprises a secondary circulation pump, a secondary-circulation water inlet main pipe, a secondary return water temperature signal meter (TT11), an outdoor temperature signal meter (TT21), and an indoor temperature signal meter (TT22), wherein the secondary return water temperature signal meter (TT11) is configured to feed back a signal to the control component; and both the outdoor temperature signal meter (TT21) and the indoor temperature signal meter (TT22) are electrically connected to the control component to feed back a real-time temperature to the control component.

5. The integrated server cabinet according to claim 1, wherein a water outlet end of the plate heat exchange component is divided into two branches, one branch is configured to return a cooled medium into the primary-circulation master water inlet pipeline in the primary circulation pipeline, and is connected between a first valve (V003) and a primary water circulation flow meter (FIT01), and the other branch is connected to the external component with a heat source need.

6. The integrated server cabinet according to claim 1, wherein in a structural layout, a length and a width of the cooling distribution unit are not greater than a length and a width of the cabinet, to reserve space for the plurality of servers; when the electric three-way regulating valve is mounted at a water inlet of the plate heat exchange component, a tee joint is diverged; or when an electric three-way regulating valve is mounted at a water outlet of the plate heat exchange component, the tee joint is converged.

7. The integrated server cabinet according to claim 1, wherein specifications of the server cabinet are determined through parameter calculation according to the following steps:
S1, determining a total power of the plurality of servers, and rounding after calculating an amplification coefficient according to the total power to determine a heat exchange power of the cooling distribution unit;
S2, calculating a flow rate of a primary circulation pump, wherein a primary circulation temperature difference Δt is obtained according to a difference between an ultimate inlet water temperature and an ultimate outlet water temperature of the plurality of servers, and the flow rate of the primary circulation pump is calculated according to the following formulas:
$$Q = cm Δ t ;$$
$$Q = c ( ρ V ) Δ t ;$$
$$V = Q / ( c ρΔ t ) ;$$
characteristic of a cooling medium comprise a freezing point, a boiling point, a density, and a specific heat capacity, wherein C represents the specific heat capacity, and represents a capability of heat required to increase a temperature of an object, a unit of the specific heat capacity is Joule per Kilogram-Celsius; m represents a mass of the object, Δt represents an amount of temperature change, of the object; p represents a density of the object, measured in kilogram per cubic meter; and V represents a volume of the object, measured in cubic meter; and the flow rate is determined by setting the amplification coefficient;
S3, calculating a lift of the primary circulation pump, selecting a pipeline specification, and determining a specific frictional resistance of a pipeline according to the selected pipeline specification, wherein
a calculation formula for a pipeline resistance loss is ΔP=L·Δp;
L is equal to a sum of a length of the pipeline, a length of an elbow, a length of a tee joint, a length of a valve group, a length of the plate heat exchange component, and a length of a server, and L is an equivalent length of a most unfavorable loop for primary circulation;
Δp represents the specific frictional resistance of the pipeline, and the lift of the primary circulation pump is greater than Δp;
S4: calculating a flow path and a lift of a secondary circulation pump, wherein a calculation process is same as a calculation process of the primary circulation pump, and a difference lies in that L is equal to a sum of the length of the pipeline, the length of the elbow, the length of the valve group, the length of the plate heat exchange component, and a length of a heating end, and L is an equivalent length of a most unfavorable loop for secondary circulation;
S5, performing plate heat exchange component model selection, wherein a power of the plate heat exchange component is equal to or slightly greater than a power sum of the plurality of servers; and then calculating a heat exchange area by performing the plate heat exchange component model selection according to a difference between a primary supply water temperature and a primary return water temperature, and a difference between a secondary supply water temperature and a secondary return water temperature; and
S6, determining model selection of the pipeline, a pipe fitting, and the valve group, wherein a pipeline with an optimal specific frictional head loss is selected by rounding up the flow rates in the primary circulation pipeline and the secondary circulation pipeline into an integer, and a square pipe is selected as a vertical pipe, thus utilizing space more effectively while marking specific frictional resistances of the pipeline and the vertical pipe be close to each other; and selecting a same pipe diameter for the pipe fitting and the valve group.

8. A control method for an integrated server cabinet allowing for waste heat recovery, comprising a primary return water temperature control mode, a waste heat utilization control mode, and a climate compensation automatic control mode that are switchable, wherein
in the primary return water temperature control mode, a primary return water temperature is controlled as follows:
1.1) setting a target primary return water temperature (TT91);
1.2) performing opening degree and rotation speed adjustment on an electric three-way regulating valve (V001) and a fan of a dry cooler (G01/G02) through a Proportional Integral Derivative (PID) algorithm module; and
1.3) making a value showing on a primary inlet water temperature signal meter (TT01) be close to the target primary return water temperature (TT91);
in the waste heat utilization control mode, the control method is as follows:
2.1) setting the target primary return water temperature (TT91) and the target secondary return water temperature (TT92);
2.2) comparing the target secondary return water temperature (TT92) with a value showing on a secondary return water temperature signal meter (TT11), and determining whether waste heat utilization is needed; performing opening degree and rotation speed adjustment on the electric three-way regulating valve (V001) and the fan of the dry cooler (G01/G02) through the PID algorithm module;
2.3) making the value showing on the primary inlet water temperature signal meter (TT01) be close to the target primary return water temperature (TT91); and
2.4) returning to step 2.1) after stabilizing for a period of time to readjust; and
in the climate compensation automatic control mode, the control method is as follows:
3.1) calculating a target secondary return water temperature (TT94) according to an outdoor temperature (TT21);
3.2) performing frequency adjustment on a secondary circulation water pump (P02) through the PID algorithm module;
3.3) making the value showing on the secondary return water temperature signal meter (TT11) be close to the target secondary return water temperature (TT94);
3.4) performing tail temperature control;
3.5) setting a target indoor temperature (TT96);
3.6) performing frequency adjustment on the secondary circulation water pump (P02) through the PID algorithm module;
3.7) making a value showing on an indoor temperature signal meter (TT22) be close to the target indoor temperature (TT96);
3.8) performing heat supply circulation water temperature control;
3.9) setting the target heat supply return water temperature (TT92);
3.10) performing frequency adjustment on the secondary circulation water pump (P02) through the PID algorithm module; and
3.11) making the value showing on the secondary return water temperature signal meter (TT11) be close to the target heat supply return water temperature (TT92).

9. The control method according to claim 8, wherein in the waste heat utilization mode control mode, the control method is specifically as follows:
1), manually setting the target primary temperature (TT91) with a first tolerance of ±2° C., wherein the target primary temperature (TT91) and the first tolerance need to be displayed on a settings screen; and manually setting the target secondary temperature (TT92) with a second tolerance of ±2° C., wherein the target secondary temperature value (TT92) and the second tolerance need to be displayed on the settings screen;
2), comparing the value showing on the secondary return water temperature signal meter (TT11) with the target secondary temperature (TT92), performing step 3) when the value showing on the secondary return water temperature signal meter (TT11) is no less than the target secondary temperature (TT92); and performing step 5) when the value showing on the secondary return water temperature signal meter (TT11) is less than the target secondary temperature (TT92);
3), setting an access of a dry cooler of the electric three-way regulating valve (V001) to 100%, setting an access of a plate heat exchange component to 0%, comparing the target primary temperature (TT91) with the value showing on the primary inlet water temperature signal meter (TT01), performing frequency adjustment on the fan of the dry cooler (G01/G02) through the PID algorithm module, and making the value showing on the primary inlet water temperature signal meter (TT01) be infinitely close to the target primary temperature (TT91);
4), setting a time interval (time02), starting to count for the time interval (time02) after heat supply balance is achieved, and automatically return to step 2) to readjust after counting is ended, wherein a readjustment time interval needs to be displayed on the settings screen;
5), setting the access of the dry cooler of the electric three-way regulating valve (V001) to 0%, and setting the access of the plate heat exchange component to 100%;
6), comparing the value showing on the primary inlet water temperature signal meter (TT01) with the target primary temperature (TT91), performing step 7) when the value showing on primary inlet water temperature signal meter (TT01) is greater than the target primary temperature (TT91); performing step 8) when the value showing on primary inlet water temperature signal meter (TT01) is less than the target primary temperature (TT91); and performing step 9) when the value showing on primary inlet water temperature signal meter (TT01) is equal to the target primary temperature (TT91);
7), slowly increasing the access of the dry cooler and slowly decreasing the access of the plate heat exchange component, and when an opening degree of the access of the plate heat exchange component is less than or equal to 20%, adjusting a rotation speed of the fan of the dry cooler (G01/G02) to slowly increase through the PID algorithm module until an effect that the value showing on primary inlet water temperature signal meter (TT01) is equal to the target primary temperature (TT91) is achieved in step 9);
8), adjusting the rotation speed of the fan of the dry cooler (G01/G02) to slowly decrease through the PID algorithm module, and after the fan of the dry cooler is stopped, slowly decreasing the access of the dry cooler and slowly increasing the access of the plate heat exchange component until the effect that the value showing on primary inlet water temperature signal meter (TT01) is equal to the target primary temperature (TT91) is achieved in step 9);
9), keeping a current opening degree of the electric three-way regulating valve (V001) and keeping a current rotation speed of the fan of the dry cooler (G01/02);
10), setting the time interval (time02), starting to count for the time interval (time02) after heat supply balance is achieved, and automatically return to step 2) to readjust after counting is ended, wherein a readjustment time interval needs to be displayed on the settings screen; and
11), on a programmable logic controller (PLC) panel, providing two settings parameters that are respectively each dynamic adjustment time (time01) and each dynamic adjustment opening degree (0P01) of the electric three-way regulating valve, wherein an upper limit of each dynamic adjustment time is set to 30 seconds, and an upper limit of each dynamic adjustment opening degree is set to 10%, to prevent a mis-operation.
